(19) United States
(12) Patent Application Publication
(10) Pub. No.: US 2024/0005066 A1
(43) Pub. Date: Jan. 4, 2024

(54) DECOUPLED PREDICTION EVALUATION

(71) Applicant: Baidu USA LLC, Sunnyvale, CA (US)

(72) Inventors: Shu JIANG, Sunnyvale, CA (US); Szu Hao WU, Sunnyvale, CA (US); Yu CAO, Sunnyvale, CA (US); Weiman LIN, Sunnyvale, CA (US); Jiangtao HU, Sunnyvale, CA (US)

(21) Appl. No.: 17/855,204

(22) Filed: Jun. 30, 2022

(51) Int. Cl. G06F 30/27

(52) U.S. Cl. CPC G06F 30/27

(57) ABSTRACT

A trajectory of an obstacle is predicted by a prediction module of the ADV. A trajectory of the ADV is determined based on the trajectory of the obstacle by a planning module of the ADV. A loss function of an analysis model of the prediction module is decomposed to multiple components with multiple weightings to generate a weighted loss function based on the trajectory of the ADV. A performance of the prediction module is evaluated based on the weighted loss function to improve the performance of the prediction module to increase a safety and comfort of the ADV.

### TECHNICAL FIELD

Embodiments of the present disclosure relate generally to autonomous driving vehicles. More particularly, embodiments of the disclosure relate to evaluating the performance of an autonomous driving vehicle (ADV).

### BACKGROUND

Vehicles operating in an autonomous mode (e.g., driverless) can relieve occupants, especially the driver, from some driving-related responsibilities. When operating in an autonomous mode, the vehicle can navigate to various locations using onboard sensors, allowing the vehicle to travel with minimal human interaction or in some cases without any passengers.

Motion planning and control are critical operations in autonomous driving. An ADV has a prediction module which predicts the trajectories of one or more obstacles under the driving circumstances and a planning module which plans a trajectory for the ADV, based on the trajectories of the one or more obstacles. The prediction module is an upstream module of the planning module in autonomous driving. The performance of the prediction module is currently evaluated only by the accuracy of the mean waypoint distance error and the final point distance error of the trajectories of the one or more obstacles. However, the accuracy in prediction of whether a vehicle intends to change a lane or speed up, sometimes cannot be reflected by the waypoint accuracy. Thus, the improvement of the performance of the prediction module may not contribute to an improvement of the performance of the ADV.

### BRIEF DESCRIPTION OF THE DRAWINGS

Embodiments of the disclosure are illustrated by way of example and not limitation in the figures of the accompanying drawings in which like references indicate similar elements.

FIG. 1 is a block diagram illustrating a networked system according to one embodiment.

FIG. 2 is a block diagram illustrating an example of an autonomous driving vehicle according to one embodiment.

FIGS. 3A-3B are block diagrams illustrating an example of an autonomous driving system used with an autonomous driving vehicle according to one embodiment.

FIG. 4 is block diagram illustrating an example of an evaluation module of an autonomous driving system according to one embodiment.

FIGS. 5A-5B are block diagrams illustrating examples of evaluating a prediction module of an autonomous driving vehicle in different driving scenarios according to one embodiment.

FIG. 6 is a flow diagram illustrating a method of evaluating a prediction module of an autonomous driving vehicle according to one embodiment.

### DETAILED DESCRIPTION

Various embodiments and aspects of the disclosures will be described with reference to details discussed below, and the accompanying drawings will illustrate the various embodiments. The following description and drawings are illustrative of the disclosure and are not to be construed as limiting the disclosure. Numerous specific details are described to provide a thorough understanding of various embodiments of the present disclosure. However, in certain instances, well-known or conventional details are not described in order to provide a concise discussion of embodiments of the present disclosures.

Reference in the specification to “one embodiment” or “an embodiment” means that a particular feature, structure, or characteristic described in conjunction with the embodiment can be included in at least one embodiment of the disclosure. The appearances of the phrase “in one embodiment” in various places in the specification do not necessarily all refer to the same embodiment.

According to some embodiments, an evaluation method and system for a prediction module of an ADV aiming to improve the overall performance of the ADV is disclosed. For example, the evaluation method and system for the prediction module could be further benefits a planning and/or a decision module of the ADV in different driving scenarios. In autonomous driving, a vehicle's behavior is well bounded by the lane/roads. The accuracy in the prediction of whether an obstacle intends to change a lane or speed up, sometimes cannot be reflected by the accuracy of the mean waypoint distance error. Instead of only measuring the mean waypoint distance error and the final point distance error of the ADV, the performance of the prediction module is evaluated based on a decoupled, or decomposed, or a weighted loss function. The terms “decoupled” or “decomposed” or “weighted” loss function are used interchangeable in this disclosure. For example, the mean waypoint distance error may be decomposed to a lateral displacement (displacement perpendicular to a lane) and a longitudinal displacement (displacement along the lane). The lateral displacement (displacement perpendicular to the lane) is more important than the longitudinal displacement (displacement along the lane), thus has a larger weighting than that of the longitudinal displacement. In this way, the planning module/decision module as well as the overall performance of the ADV is improved with the improvement of the performance of the prediction module, thereby improving the safety and comfort of the ADV.

According to some embodiments, a trajectory of an obstacle is predicted by a prediction module of the ADV. A trajectory of the ADV is planned based on the trajectory of the obstacle by a planning module of the ADV. A loss function of an analysis model of the prediction module is decomposed into multiple components with multiple weightings to generate a weighted loss function based on the trajectory of the ADV. A performance of the prediction module is evaluated based on the weighted loss function to improve the performance of the prediction module to increase a safety and comfort of the ADV.

According to some embodiments, a non-transitory machine-readable medium having instructions stored therein is disclosed. The instructions, when executed by a processor, cause the processor to predict a trajectory of an obstacle by a prediction module of the ADV; plan a trajectory of the ADV based on the trajectory of the obstacle by a planning module of the ADV; decompose a loss function of an analysis model of the prediction module to multiple components with multiple weightings into generate a weighted loss function based on the trajectory of the ADV; and evaluate a performance of the prediction module based on the weighted loss function to improve the performance of the prediction module to increase a safety and comfort of the ADV.

According to some embodiments, a data processing system is disclosed. The data processing system comprises a processor; and a memory coupled to the processor to store instructions. The instructions, when executed by a processor, cause the processor to predict a trajectory of an obstacle by a prediction module of the ADV; plan a trajectory of the ADV based on the trajectory of the obstacle by a planning module of the ADV; decompose a loss function of an analysis model of the prediction module into multiple components with multiple weightings to generate a weighted loss function based on the trajectory of the ADV; and evaluate a performance of the prediction module based on the weighted loss function to improve the performance of the prediction module to increase a safety and comfort of the ADV.

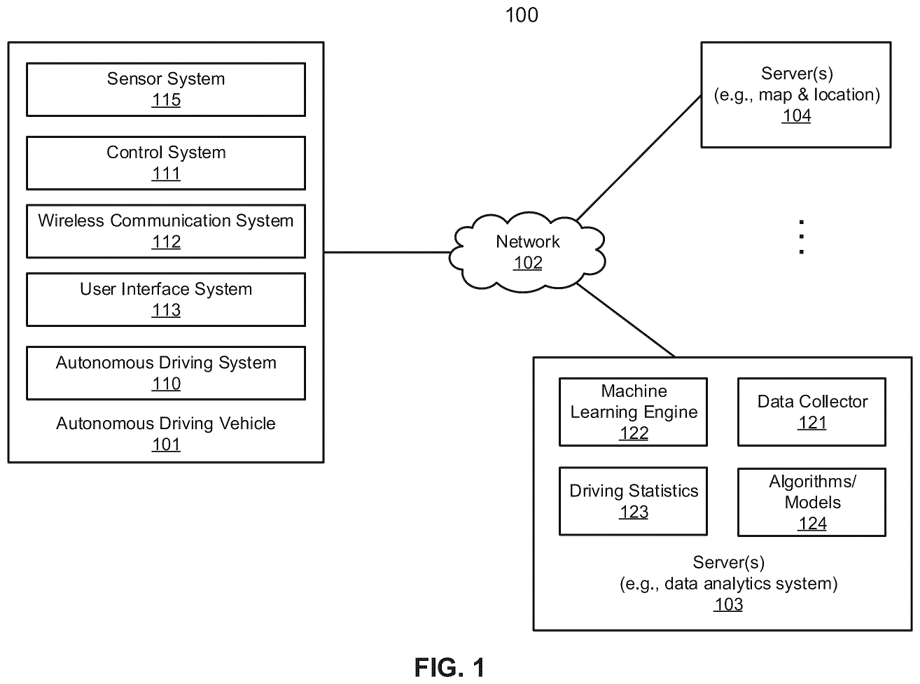

FIG. 1 is a block diagram illustrating an autonomous driving network configuration according to one embodiment of the disclosure. Referring to FIG. 1, network configuration 100 includes autonomous driving vehicle (ADV) 101 that may be communicatively coupled to one or more servers 103-104 over a network 102. Although there is one ADV shown, multiple ADVs can be coupled to each other and/or coupled to servers 103-104 over network 102. Network 102 may be any type of networks such as a local area network (LAN), a wide area network (WAN) such as the Internet, a cellular network, a satellite network, or a combination thereof, wired or wireless. Server(s) 103-104 may be any kind of servers or a cluster of servers, such as Web or cloud servers, application servers, backend servers, or a combination thereof. Servers 103-104 may be data analytics servers, content servers, traffic information servers, map and point of interest (MPOI) servers, or location servers, etc.

An ADV refers to a vehicle that can be configured to in an autonomous mode in which the vehicle navigates through an environment with little or no input from a driver. Such an ADV can include a sensor system having one or more sensors that are configured to detect information about the environment in which the vehicle operates. The vehicle and its associated controller(s) use the detected information to navigate through the environment. ADV 101 can operate in a manual mode, a full autonomous mode, or a partial autonomous mode.

In one embodiment, ADV 101 includes, but is not limited to, autonomous driving system (ADS) 110, vehicle control system 111, wireless communication system 112, user interface system 113, and sensor system 115. ADV 101 may further include certain common components included in ordinary vehicles, such as, an engine, wheels, steering wheel, transmission, etc., which may be controlled by vehicle control system 111 and/or ADS 110 using a variety of communication signals and/or commands, such as, for example, acceleration signals or commands, deceleration signals or commands, steering signals or commands, braking signals or commands, etc.

Components 110-115 may be communicatively coupled to each other via an interconnect, a bus, a network, or a combination thereof. For example, components 110-115 may be communicatively coupled to each other via a controller area network (CAN) bus. A CAN bus is a vehicle bus standard designed to allow microcontrollers and devices to communicate with each other in applications without a host computer. It is a message-based protocol, designed originally for multiplex electrical wiring within automobiles, but is also used in many other contexts.

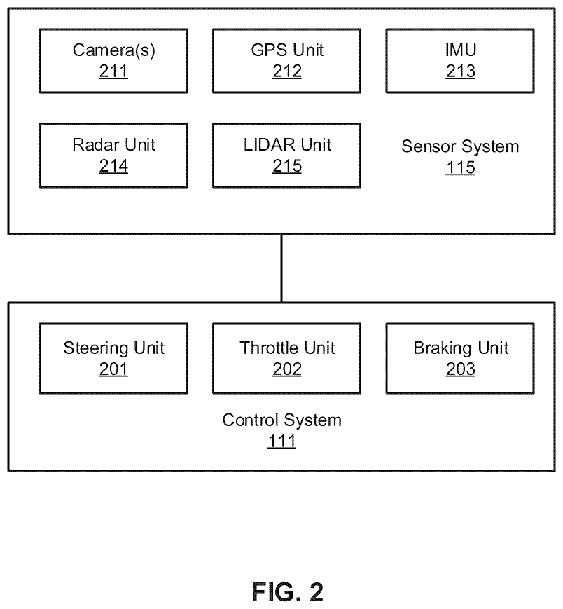

Referring now to FIG. 2, in one embodiment, sensor system 115 includes, but it is not limited to, one or more cameras 211, global positioning system (GPS) unit 212, inertial measurement unit (IMU) 213, radar unit 214, and a light detection and range (LIDAR) unit 215. GPS system 212 may include a transceiver operable to provide information regarding the position of the ADV. IMU unit 213 may sense position and orientation changes of the ADV based on inertial acceleration. Radar unit 214 may represent a system that utilizes radio signals to sense objects within the local environment of the ADV. In some embodiments, in addition to sensing objects, radar unit 214 may additionally sense the speed and/or heading of the objects. LIDAR unit 215 may sense objects in the environment in which the ADV is located using lasers. LIDAR unit 215 could include one or more laser sources, a laser scanner, and one or more detectors, among other system components. Cameras 211 may include one or more devices to capture images of the environment surrounding the ADV. Cameras 211 may be still cameras and/or video cameras. A camera may be mechanically movable, for example, by mounting the camera on a rotating and/or tilting a platform.

Sensor system 115 may further include other sensors, such as, a sonar sensor, an infrared sensor, a steering sensor, a throttle sensor, a braking sensor, and an audio sensor (e.g., microphone). An audio sensor may be configured to capture sound from the environment surrounding the ADV. A steering sensor may be configured to sense the steering angle of a steering wheel, wheels of the vehicle, or a combination thereof. A throttle sensor and a braking sensor sense the throttle position and braking position of the vehicle, respectively. In some situations, a throttle sensor and a braking sensor may be integrated as an integrated throttle/braking sensor.

In one embodiment, vehicle control system 111 includes, but is not limited to, steering unit 201, throttle unit 202 (also referred to as an acceleration unit), and braking unit 203. Steering unit 201 is to adjust the direction or heading of the vehicle. Throttle unit 202 is to control the speed of the motor or engine that in turn controls the speed and acceleration of the vehicle. Braking unit 203 is to decelerate the vehicle by providing friction to slow the wheels or tires of the vehicle. Note that the components as shown in FIG. 2 may be implemented in hardware, software, or a combination thereof.

Referring back to FIG. 1, wireless communication system 112 is to allow communication between ADV 101 and external systems, such as devices, sensors, other vehicles, etc. For example, wireless communication system 112 can wirelessly communicate with one or more devices directly or via a communication network, such as servers 103-104 over network 102. Wireless communication system 112 can use any cellular communication network or a wireless local area network (WLAN), e.g., using WiFi to communicate with another component or system. Wireless communication system 112 could communicate directly with a device (e.g., a mobile device of a passenger, a display device, a speaker within vehicle 101), for example, using an infrared link, Bluetooth, etc. User interface system 113 may be part of peripheral devices implemented within vehicle 101 including, for example, a keyboard, a touch screen display device, a microphone, and a speaker, etc.

Some or all of the functions of ADV 101 may be controlled or managed by ADS 110, especially when operating in an autonomous driving mode. ADS 110 includes the necessary hardware (e.g., processor(s), memory, storage) and software (e.g., operating system, planning and routing programs) to receive information from sensor system 115, control system 111, wireless communication system 112, and/or user interface system 113, process the received information, plan a route or path from a starting point to a destination point, and then drive vehicle 101 based on the planning and control information. Alternatively, ADS 110 may be integrated with vehicle control system 111.

For example, a user as a passenger may specify a starting location and a destination of a trip, for example, via a user interface. ADS 110 obtains the trip related data. For example, ADS 110 may obtain location and route data from an MPOI server, which may be a part of servers 103-104. The location server provides location services and the MPOI server provides map services and the POIs of certain locations. Alternatively, such location and MPOI information may be cached locally in a persistent storage device of ADS 110.

While ADV 101 is moving along the route, ADS 110 may also obtain real-time traffic information from a traffic information system or server (TIS). Note that servers 103-104 may be operated by a third party entity. Alternatively, the functionalities of servers 103-104 may be integrated with ADS 110. Based on the real-time traffic information, MPOI information, and location information, as well as real-time local environment data detected or sensed by sensor system 115 (e.g., obstacles, objects, nearby vehicles), ADS 110 can plan an optimal route and drive vehicle 101, for example, via control system 111, according to the planned route to reach the specified destination safely and efficiently.

Server 103 may be a data analytics system to perform data analytics services for a variety of clients. In one embodiment, data analytics system 103 includes data collector 121 and machine learning engine 122. Data collector 121 collects driving statistics 123 from a variety of vehicles, either ADVs or regular vehicles driven by human drivers. Driving statistics 123 include information indicating the driving commands (e.g., throttle, brake, steering commands) issued and responses of the vehicles (e.g., speeds, accelerations, decelerations, directions) captured by sensors of the vehicles at different points in time. Driving statistics 123 may further include information describing the driving environments at different points in time, such as, for example, routes (including starting and destination locations), MPOIs, road conditions, weather conditions, etc.

Based on driving statistics 123, machine learning engine 122 generates or trains a set of rules, algorithms, and/or predictive models 124 for a variety of purposes. Algorithms 124 can then be uploaded on ADVs to be utilized during autonomous driving in real-time.

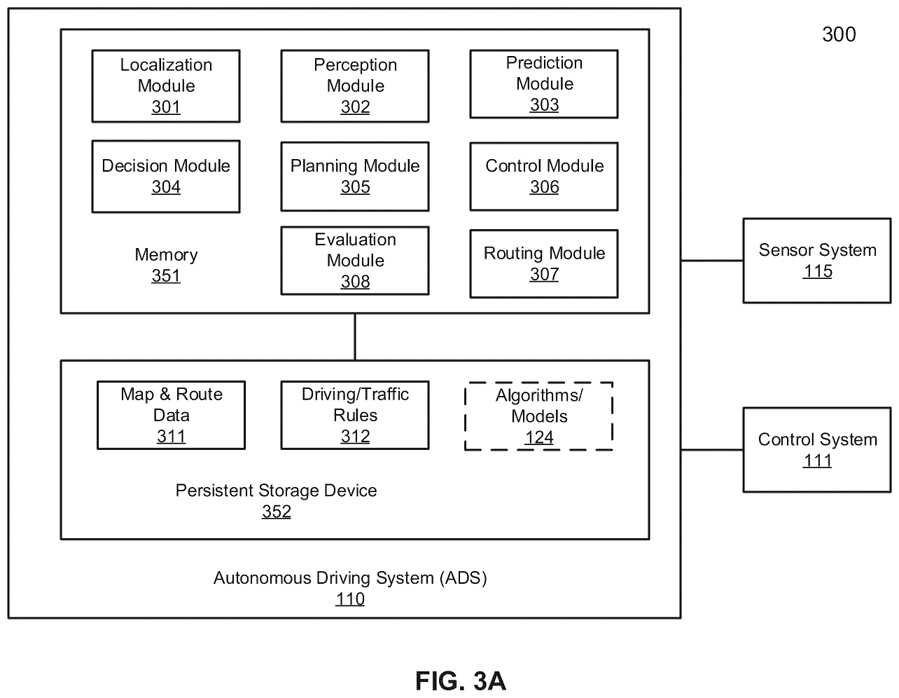

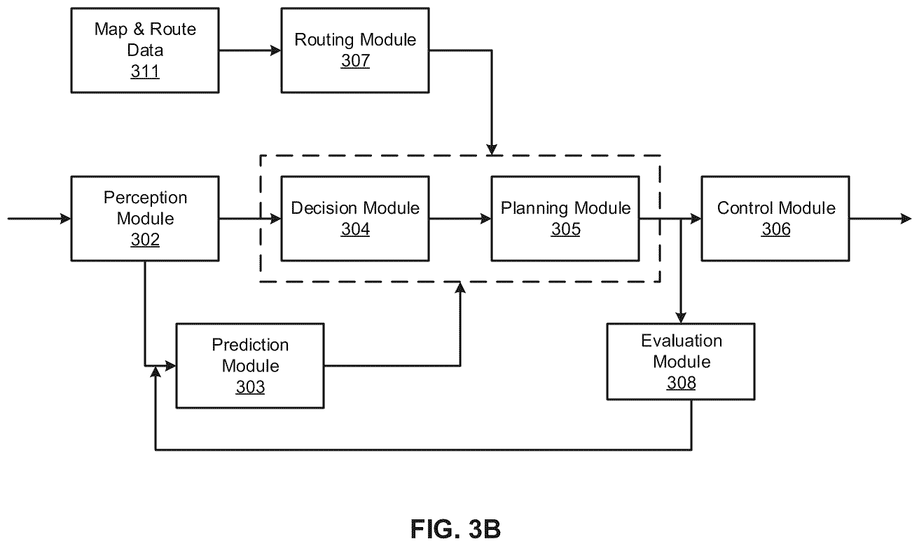

FIGS. 3A and 3B are block diagrams illustrating an example of an autonomous driving system used with an ADV according to one embodiment. System 300 may be implemented as a part of ADV 101 of FIG. 1 including, but is not limited to, ADS 110, control system 111, and sensor system 115. Referring to FIGS. 3A-3B, ADS 110 includes, but is not limited to, localization module 301, perception module 302, prediction module 303, decision module 304, planning module 305, control module 306, and routing module 307.

Some or all of modules 301-307 may be implemented in software, hardware, or a combination thereof. For example, these modules may be installed in persistent storage device 352, loaded into memory 351, and executed by one or more processors (not shown). Note that some or all of these modules may be communicatively coupled to or integrated with some or all modules of vehicle control system 111 of FIG. 2. Some of modules 301-307 may be integrated together as an integrated module.

Localization module 301 determines a current location of ADV 300 (e.g., leveraging GPS unit 212) and manages any data related to a trip or route of a user. Localization module 301 (also referred to as a map and route module) manages any data related to a trip or route of a user. A user may log in and specify a starting location and a destination of a trip, for example, via a user interface. Localization module 301 communicates with other components of ADV 300, such as map and route data 311, to obtain the trip related data. For example, localization module 301 may obtain location and route data from a location server and a map and POI (MPOI) server. A location server provides location services and an MPOI server provides map services and the POIs of certain locations, which may be cached as part of map and route data 311. While ADV 300 is moving along the route, localization module 301 may also obtain real-time traffic information from a traffic information system or server.

Based on the sensor data provided by sensor system 115 and localization information obtained by localization module 301, a perception of the surrounding environment is determined by perception module 302. The perception information may represent what an ordinary driver would perceive surrounding a vehicle in which the driver is driving. The perception can include the lane configuration, traffic light signals, a relative position of another vehicle, a pedestrian, a building, crosswalk, or other traffic related signs (e.g., stop signs, yield signs), etc., for example, in a form of an object. The lane configuration includes information describing a lane or lanes, such as, for example, a shape of the lane (e.g., straight or curvature), a width of the lane, how many lanes in a road, one-way or two-way lane, merging or splitting lanes, exiting lane, etc.

Perception module 302 may include a computer vision system or functionalities of a computer vision system to process and analyze images captured by one or more cameras in order to identify objects and/or features in the environment of the ADV. The objects can include traffic signals, road way boundaries, other vehicles, pedestrians, and/or obstacles, etc. The computer vision system may use an object recognition algorithm, video tracking, and other computer vision techniques. In some embodiments, the computer vision system can map an environment, track objects, and estimate the speed of objects, etc. Perception module 302 can also detect objects based on other sensors data provided by other sensors such as a radar and/or LIDAR.

For each of the objects, prediction module 303 predicts what the object will behave under the circumstances. For example, prediction module 303 predicts a trajectory of the object. The prediction is performed based on the perception data perceiving the driving environment at the point in time in view of a set of map/rout information 311 and traffic rules 312. For example, if the object is a vehicle at an opposing direction and the current driving environment includes an intersection, prediction module 303 will predict whether the vehicle will likely move straight forward or make a turn. If the perception data indicates that the intersection has no traffic light, prediction module 303 may predict that the vehicle may have to fully stop prior to enter the intersection. If the perception data indicates that the vehicle is currently at a left-turn only lane or a right-turn only lane, prediction module 303 may predict that the vehicle will more likely make a left turn or right turn respectively.

For each of the objects, decision module 304 makes a decision regarding how to handle the object. For example, for a particular object (e.g., another vehicle in a crossing route) as well as its metadata describing the object (e.g., a speed, direction, turning angle), decision module 304 decides how to encounter the object (e.g., overtake, yield, stop, pass). Decision module 304 may make such decisions according to a set of rules such as traffic rules or driving rules 312, which may be stored in persistent storage device 352.

Routing module 307 is configured to provide one or more routes or paths from a starting point to a destination point. For a given trip from a start location to a destination location, for example, received from a user, routing module 307 obtains route and map information 311 and determines all possible routes or paths from the starting location to reach the destination location. Routing module 307 may generate a reference line in a form of a topographic map for each of the routes it determines from the starting location to reach the destination location. A reference line refers to an ideal route or path without any interference from others such as other vehicles, obstacles, or traffic condition. That is, if there is no other vehicle, pedestrians, or obstacles on the road, an ADV should exactly or closely follows the reference line. The topographic maps are then provided to decision module 304 and/or planning module 305. Decision module 304 and/or planning module 305 examine all of the possible routes to select and modify one of the most optimal routes in view of other data provided by other modules such as traffic conditions from localization module 301, driving environment perceived by perception module 302, and traffic condition predicted by prediction module 303. The actual path or route for controlling the ADV may be close to or different from the reference line provided by routing module 307 dependent upon the specific driving environment at the point in time.

Based on a decision for each of the objects perceived, planning module 305 plans a trajectory or a path or route for the ADV, as well as driving parameters (e.g., distance, speed, and/or turning angle), using a reference line provided by routing module 307 as a basis. That is, for a given object, decision module 304 decides what to do with the object, while planning module 305 determines how to do it. For example, for a given object, decision module 304 may decide to pass the object, while planning module 305 may determine whether to pass on the left side or right side of the object. Planning and control data is generated by planning module 305 including information describing how vehicle 300 would move in a next moving cycle (e.g., next route/path segment). For example, the planning and control data may instruct vehicle 300 to move 10 meters at a speed of 30 miles per hour (mph), then change to a right lane at the speed of 25 mph.

Based on the planning and control data, control module 306 controls and drives the ADV, by sending proper commands or signals to vehicle control system 111, according to a trajectory or a route or path defined by the planning and control data. The planning and control data include sufficient information to drive the vehicle from a first point to a second point of a route or path using appropriate vehicle settings or driving parameters (e.g., throttle, braking, steering commands) at different points in time along the path or route.

In one embodiment, the planning phase is performed in a number of planning cycles, also referred to as driving cycles, such as, for example, in every time interval of 100 milliseconds (ms). For each of the planning cycles or driving cycles, one or more control commands will be issued based on the planning and control data. That is, for every 100 ms, planning module 305 plans a next route segment or path segment, for example, including a target position and the time required for the ADV to reach the target position. Alternatively, planning module 305 may further specify the specific speed, direction, and/or steering angle, etc. In one embodiment, planning module 305 plans a route segment or path segment for the next predetermined period of time such as 5 seconds. For each planning cycle, planning module 305 plans a target position for the current cycle (e.g., next 5 seconds) based on a target position planned in a previous cycle. Control module 306 then generates one or more control commands (e.g., throttle, brake, steering control commands) based on the planning and control data of the current cycle.

Note that decision module 304 and planning module 305 may be integrated as an integrated module. Decision module 304/planning module 305 may include a navigation system or functionalities of a navigation system to determine a driving path for the ADV. For example, the navigation system may determine a series of speeds and directional headings to affect movement of the ADV along a path that substantially avoids perceived obstacles while generally advancing the ADV along a roadway-based path leading to an ultimate destination. The destination may be set according to user inputs via user interface system 113. The navigation system may update the driving path dynamically while the ADV is in operation. The navigation system can incorporate data from a GPS system and one or more maps so as to determine the driving path for the ADV.

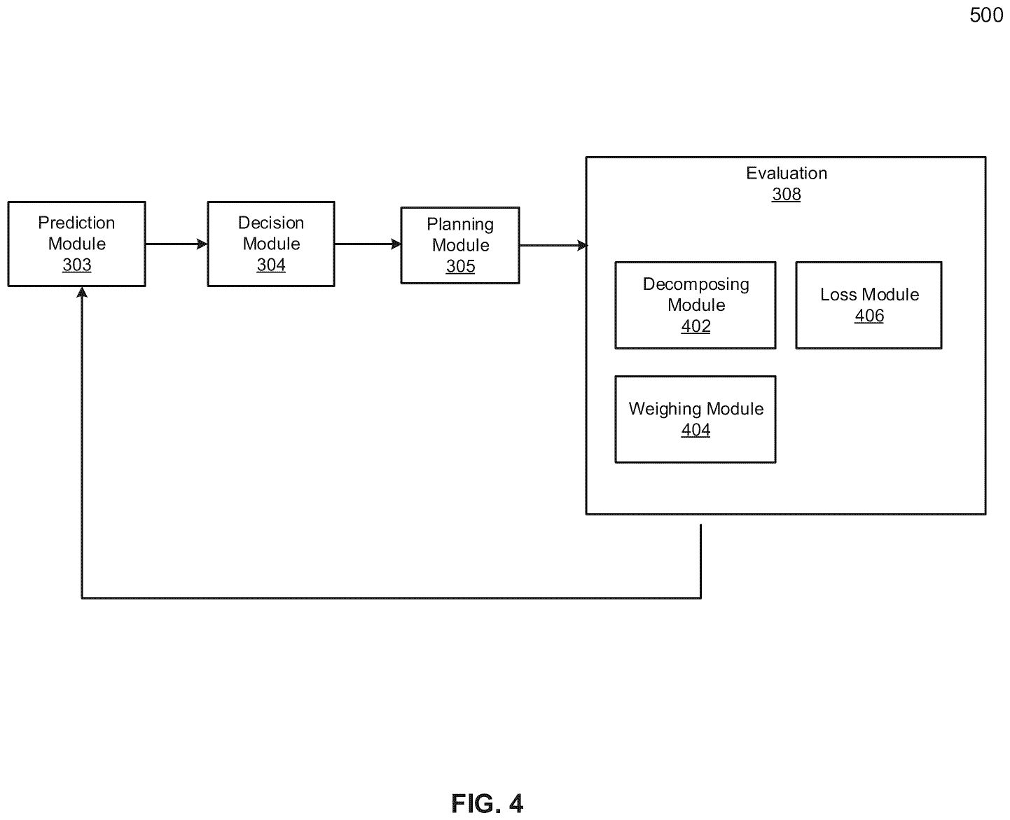

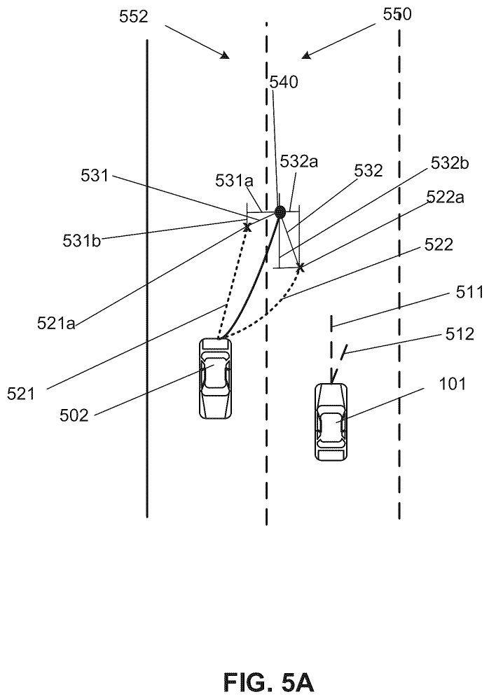

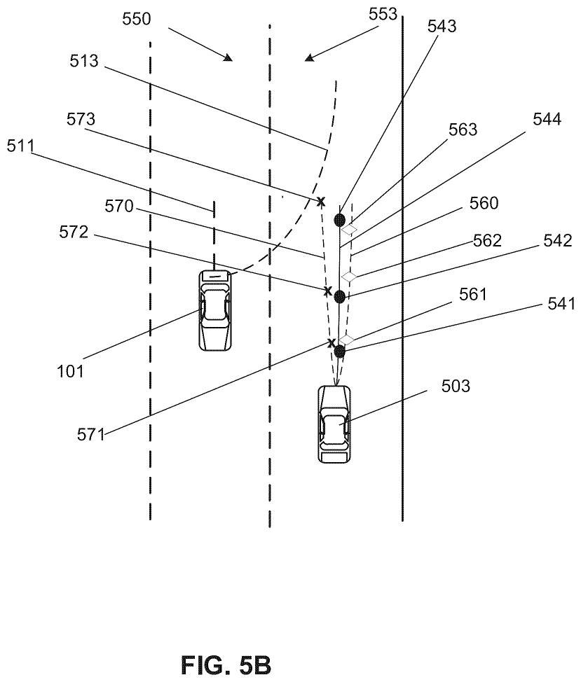

FIG. 4 is block diagram illustrating an example of an evaluation module of an autonomous driving system according to one embodiment. FIGS. 5A-5B are block diagrams illustrating examples of evaluating a prediction module of an autonomous driving vehicle in different driving scenarios according to one embodiment. Referring to FIGS. 4, 5A-5B, the prediction module 303 serves the decision module 304 and the planning module 305. Thus, only measuring the accuracy of the mean waypoint distance error and the final point distance error of a predicated trajectories of an obstacle compared to the ground truth may not benefit the decision module 304 and/or the planning module 305. For example, a waypoint may be a set of coordinates that identify a point in physical space. The accuracy in the prediction of whether an obstacle intends to change a lane or speed up, sometimes cannot be reflected by the accuracy of the mean waypoint distance error. In order to improve the overall performance of the ADV, the performance of the prediction module is evaluated based on a decomposed or weighted loss function. In this way, the overall performance of the ADV is improved with the improvement of the performance of the prediction module, thereby improving the safety and comfort of the ADV.

For example, as illustrated in FIG. 5A, the ADV 101 may be driving on a lane 550. An obstacle 502 may be driving near the ADV 101 on an adjacent lane 552. The obstacle 502 may be a moving vehicle such as a car, truck, bus, motorcycle, etc. The prediction module 303 may predict a trajectory for the obstacle 502. For example, the prediction module 303 may predict a trajectory 521 or trajectory 522 of the obstacle 502. Based on the trajectory 521 or trajectory 522 of the obstacle 502, the planning module 305 may plan a trajectory 511 or 512 for the ADV 101.

Currently, the performance of the prediction module 303 is evaluated based on a mean waypoint distance error and/or a final point distance error from a predicted location of the obstacle to a ground truth location (e.g., obtained by record files). For example, the mean waypoint distance error may be an average of waypoint distance errors of multiple points, while the final point distance error may be a distance error of a final point (e.g., 521a, or 522a). However, in autonomous driving, a vehicle's behavior is well bounded by the lane/roads. The accuracy in prediction of whether the obstacle intends to change a lane or speed up, sometimes cannot be reflected by the mean waypoint distance error and/or the final point distance error. For example, as illustrated in FIG. 5A, the mean waypoint distance error/final point distance error 531 (from a predicted location 521a of the obstacle 502 to a ground truth location 540) for the predicted trajectory 521 is smaller than mean waypoint distance error/final point distance error 532 (from a predicted location 522a of the obstacle 502 to the ground truth location 540) for the predicted trajectory 522. Based on the predicted trajectory 521, the obstacle 502 would not cut into the lane 550 following the predicted trajectory 521. Thus, the planning module 305 may plan the trajectory 511 of the ADV to continue to go straight along the lane 550. Then, the ADV 101 may collide with the obstacle 502, or have to use a hard brake to be near a collision with the obstacle 502.

A new evaluation system for evaluating the performance of the prediction module based on a decoupled or decomposed or weighted loss function will improve the overall performance of the ADV. Referring to FIG. 4, the prediction module 303 of the ADV 101 predicts the trajectory (e.g., 521 or 522) of the obstacle 502. The decision module 304 makes s decision based on the trajectory (e.g., 521 or 522) of the obstacle 502 as well as sensor information, map information, the route of the ADV, etc. The planning module 305 plans a trajectory (e.g., 511 or 512) for the ADV 101 according to the decision of the decision module 304 based on the trajectory (e.g., 521 or 522) of the obstacle 502 as well as sensor information, map information, the route of the ADV, etc. The evaluation module 308 decomposes a loss function of an analysis model of the prediction module 303 into multiple components with multiple weightings to generate a weighted loss function based on the trajectory (e.g., 511 or 512) of the ADV 101 and evaluate the performance of the prediction module 303 based on the weighted loss function.

As illustrated in FIG. 4, the evaluation module 308 may include a decomposing module 402, weighting module 404, and loss module 406. The decomposing module 402 may be configured to decomposes the loss function of the analysis model of the prediction module 303 into multiple components. The weighting module 404 may be configured to determine the multiple weightings for the multiple components based on the trajectory (e.g., 511 or 512) of the ADV 101. In one embodiment, the weighting module 404 may be configured to determine each weighing of the multiple weightings based on an impact of a weighting to the trajectory of the ADV. In one embodiment, the weighting module 404 may be configured to determine each weighing of the multiple weightings based on a performance of the planning module based on the trajectory of the ADV. For example, the performance of the planning module may be determined by a set of metrics, including a collision, a comfort level, a violation of traffic rules, or a near collision of a planned trajectory.

The loss module 406 may be configured to determine a loss from the plurality of losses. The loss function may include a plurality of losses corresponding to a plurality of driving scenarios. Each loss may correspond to a driving scenario. The loss module 406 may determine a driving scenario from the plurality of driving scenarios, and determine a corresponding loss from the plurality of losses in response to the driving scenario. The evaluation module 308 may include more or less modules than modules 404, 404, 406. Some of the modules 404, 404, 406 may be integrated as well.

Referring to FIG. 5A, which illustrates an example of a driving scenario in which the obstacle 502 may cut into or change to the lane of the ADV. The Loss function may have different losses. There may be many different driving scenarios. Each of the different driving scenarios may have a different loss. In this scenario, instead of using just a mean waypoint/final point distance error, the loss may be designed to include a weighted lateral mean waypoint/final point distance error (e.g., 531a, 532a) and a weighted longitudinal mean waypoint/final point distance error (e.g., 531b, 532b) from the ground truth (e.g., 540) to the predicted location (e.g., 521a, 522a). The mean waypoint/final point distance error may be decomposed to the lateral mean waypoint/final point distance error and the longitudinal mean waypoint/final point distance error from the ground truth to the predicted location. As illustrated in FIG. 5A, for the predicted trajectory 522, the mean waypoint/final point distance error 632, from the ground truth 540 to the predicted location 522a, may be decomposed to the lateral mean waypoint/final point distance error 532a and the longitudinal mean waypoint/final point distance error 532b; for the predicted trajectory 521, the mean waypoint/final point distance error 531, from the ground truth 540 to the predicted location 521a, may be decomposed to a lateral mean waypoint/final point distance error 531a and a longitudinal mean waypoint/final point distance error 531b. For example, the lateral mean waypoint/final point distance error (e.g., 531a or 532a) may be weighted larger than the longitudinal mean waypoint/final point distance error (e.g., 531b, 532b) because the lateral mean waypoint/final point distance error may have more impact to the performance of the planning module 305 (e.g., the planned trajectory of the ADV). More accurate prediction of the lateral mean waypoint/final point distance error (e.g., 531a or 532a) may improve the planned trajectory (e.g., 511, or 512) of the ADV. The loss function may include a weighted loss function based on the weighted lateral mean waypoint/final point distance error and the weighted longitudinal mean waypoint/final point distance error from the ground truth to the predicted location, where the weighting of the lateral mean waypoint/final point distance error is larger than the weighting of the longitudinal mean waypoint/final point distance error. For example, the loss function for this driving scenario may be expressed as:

Loss1=W1*lateral mean waypoint/final point distance error+W2*longitudinal mean waypoint/final point distance error,

wherein W1 is the weighting of the lateral mean waypoint/final point distance error, and W2 is the weighting of the longitudinal mean waypoint/final point distance error.

According to the weighted loss function, the prediction module may predict the trajectory 522, thus, the obstacle 502 may cut into move into the lane 550 from the lane 552. Consequently, the planning module 305 may plan the trajectory 512 of the ADV to move away from the obstacle 602, make a lane change and/or slow down to prepare for an emergency stop. Then, the ADV 101 would not collide with the obstacle 502, nor have to use a hard brake. In this scenario, the planning module 305 may have a good performance. The overall performance of the ADV 101 may be improved.

Referring to FIG. 5B, which illustrates an example of another driving scenario in which the ADV 101 may need to make a lane change from the lane 550 to a lane 553 of an obstacle 503. In this scenario, whether the obstacle 503 is slowing down to let the ADV 101 into the lane 553 or speeding up not letting the ADV 101 into the lane 553 has an impact to the planning module of the ADV. If the obstacle 503 is slowing down to let the ADV 101 into the lane 553, the planning module may plan the trajectory 513 of the ADV 101 to make the lane change; on the other hand, if the obstacle 503 is speeding up not letting the ADV 101 into the lane 553, the planning module may plan the trajectory 511 of the ADV 101 to continue to go straight ahead and wait for another opportunity to make the lane change.

The prediction module 303 may predict a trajectory 560 including predicted obstacle locations 561, 562, 563 or a trajectory 570 including predicted obstacle locations 571, 572, 573. The location errors of the predicted obstacle locations 571, 572, 573 of the trajectory 570, compared to the ground truth points 541, 542, 543 of the ground truth trajectory 540 (e.g., from record files), may be larger than the location errors of the predicted obstacle locations 561, 562, 563 of the trajectory 560 compared to the ground truth points 541, 542, 543. However, based on the predicted obstacle locations 561, 562, 563 of the trajectory 560, the obstacle 503 is slowing down since the distance between the predicted location 562 and 563 is smaller than the distance between the predicted location 561 and 562, thus, the ADV 101 may make the lane change, resulting a collision or near collision. But if based on the predicted obstacle locations 571, 572, 573 of the trajectory 570, the obstacle 503 is speeding up since the distance between the predicted location 572 and 573 is larger than the distance between the predicted location 571 and 572, thus, the ADV 101 may not make the lane change, avoiding the collision or near collision.

In this scenario, the loss function may include a location error. The prediction module 303 may decompose the location error into a speed error with a speed weighting and a heading error with a heading weighting. Since the speed of the obstacle 503 has a larger impact to the trajectory of the ADV 101 than the heading of the obstacle 503, the speed weighting is larger than the heading weighting. The prediction module 303 may generate the weighted loss function using the speed error with the speed weighting and the heading error with the heading weighting. Based on this weighted loss function, in which the speed weighting is larger than the heading weighting, the prediction 303 may predict the trajectory 570 of the obstacle 503. Accordingly, the planning module 305 of the ADV 101 may plan the trajectory 511 to continue to go straight ahead, not making the lane change, thereby improving the safety and comfort of the ADV 101.

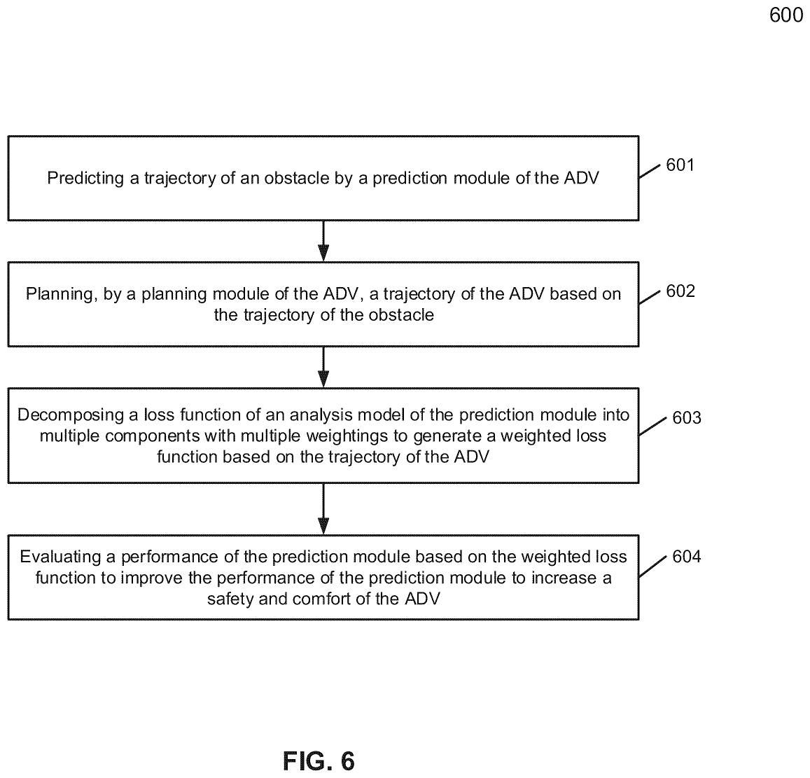

FIG. 6 is a flow diagram illustrating a method of evaluating a prediction module of an autonomous driving vehicle according to one embodiment. Method 600 may be performed by processing logic which may include software, hardware, or a combination thereof. Referring to FIG. 6, in operation 601, processing logic predicts a trajectory of an obstacle by a prediction module of the ADV.

In operation 602, processing logic plans a trajectory of the ADV based on the trajectory of the obstacle by a planning module of the ADV. In operation 603, processing logic decomposes a loss function of an analysis model of the prediction module into multiple components with multiple weightings to generate a weighted loss function based on the trajectory of the ADV.

In one embodiment, the loss function may include a mean waypoint distance error. Processing logic may decompose the mean waypoint distance error into a first mean waypoint distance error perpendicular to a lane with a first weighting and a second mean waypoint distance error along the lane with a second weighting, where the first weighting is larger than the second weighting.

In one embodiment, the loss function may include a final point distance error. Processing logic may decompose the final point distance error into a first final point distance error perpendicular to a lane with a first weighting and a second final point distance error along the lane with a second weighting, where the first weighting is larger than the second weighting.

In one embodiment, the loss function may include a location error. Processing logic may decompose the location error into a speed error with a first weighting and a heading error with a second weighting, where the first weighting is larger than the second weighting.

In one embodiment, processing logic may determine each weighing of the multiple weightings based on an impact of a weighting to the trajectory of the ADV. In one embodiment, processing logic may determine each weighing of the multiple weightings based on a performance of the planning module based on the trajectory of the ADV.

In one embodiment, the loss function may include a plurality of losses corresponding to a plurality of driving scenarios, where each loss may correspond to a driving scenario. In one embodiment, processing logic may determine a driving scenario from the plurality of driving scenarios, and may determine a corresponding loss from the plurality of losses in response to the driving scenario.

In operation 604, processing logic evaluates a performance of the prediction module based on the weighted loss function to improve the performance of the prediction module to increase a safety and comfort of the ADV.

Note that some or all of the components as shown and described above may be implemented in software, hardware, or a combination thereof. For example, such components can be implemented as software installed and stored in a persistent storage device, which can be loaded and executed in a memory by a processor (not shown) to carry out the processes or operations described throughout this application. Alternatively, such components can be implemented as executable code programmed or embedded into dedicated hardware such as an integrated circuit (e.g., an application specific IC or ASIC), a digital signal processor (DSP), or a field programmable gate array (FPGA), which can be accessed via a corresponding driver and/or operating system from an application. Furthermore, such components can be implemented as specific hardware logic in a processor or processor core as part of an instruction set accessible by a software component via one or more specific instructions.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities.

It should be borne in mind, however, that all of these and similar terms are to be associated with the appropriate physical quantities and are merely convenient labels applied to these quantities. Unless specifically stated otherwise as apparent from the above discussion, it is appreciated that throughout the description, discussions utilizing terms such as those set forth in the claims below, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Embodiments of the disclosure also relate to an apparatus for performing the operations herein. Such a computer program is stored in a non-transitory computer readable medium. A machine-readable medium includes any mechanism for storing information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices).

The processes or methods depicted in the preceding figures may be performed by processing logic that comprises hardware (e.g. circuitry, dedicated logic, etc.), software (e.g., embodied on a non-transitory computer readable medium), or a combination of both. Although the processes or methods are described above in terms of some sequential operations, it should be appreciated that some of the operations described may be performed in a different order. Moreover, some operations may be performed in parallel rather than sequentially.

Embodiments of the present disclosure are not described with reference to any particular programming language. It will be appreciated that a variety of programming languages may be used to implement the teachings of embodiments of the disclosure as described herein.

In the foregoing specification, embodiments of the disclosure have been described with reference to specific exemplary embodiments thereof. It will be evident that various modifications may be made thereto without departing from the broader spirit and scope of the disclosure as set forth in the following claims. The specification and drawings are, accordingly, to be regarded in an illustrative sense rather than a restrictive sense.

What is claimed is:

1. A computer-implemented method of operating an autonomous driving vehicle (ADV), the method comprising:
predicting a trajectory of an obstacle by a prediction module of the ADV;
planning a trajectory of the ADV based on the trajectory of the obstacle by a planning module of the ADV;
decomposing a loss function of an analysis model of the prediction module into multiple components with multiple weightings to generate a weighted loss function based on the trajectory of the ADV; and
evaluating a performance of the prediction module based on the weighted loss function to improve the performance of the prediction module to increase a safety and comfort of the ADV.

2. The method of claim 1, wherein the loss function includes a mean waypoint distance error, and wherein the decomposing the loss function of the analysis model of the prediction module into the multiple components with the multiple weightings comprises
decomposing the mean waypoint distance error into a first mean waypoint distance error perpendicular to a lane with a first weighting and a second mean waypoint distance error along the lane with a second weighting, wherein the first weighting is larger than the second weighting.

3. The method of claim 1, wherein the loss function includes a final point distance error, and wherein the decomposing the loss function of the analysis model of the prediction module into the multiple components with the multiple weightings comprises
decomposing the final point distance error into a first final point distance error perpendicular to a lane with a first weighting and a second final point distance error along the lane with a second weighting, wherein the first weighting is larger than the second weighting.

4. The method of claim 1, wherein the loss function includes a location error, and wherein the decomposing the loss function of the analysis model of the prediction module into the multiple components with the multiple weightings comprises
decomposing the location error into a speed error with a first weighting and a heading error with a second weighting, wherein the first weighting is larger than the second weighting.

5. The method of claim 1, further comprising
determining each weighing of the multiple weightings based on an impact of a weighting to the trajectory of the ADV.

6. The method of claim 1, further comprising
determining each weighing of the multiple weightings based on a performance of the planning module based on the trajectory of the ADV.

7. The method of claim 1, wherein the loss function includes a plurality of losses corresponding to a plurality of driving scenarios, each loss corresponding to a driving scenario.

8. The method of claim 7, further comprising
determining a driving scenario from the plurality of driving scenarios;
determining a corresponding loss from the plurality of losses in response to the driving scenario.

9. A non-transitory machine-readable medium having instructions stored therein, which when executed by a processor, cause the processor to:
predict a trajectory of an obstacle by a prediction module of an autonomous driving vehicle (ADV);
plan a trajectory of the ADV based on the trajectory of the obstacle by a planning module of the ADV;
decompose a loss function of an analysis model of the prediction module into multiple components with multiple weightings to generate a weighted loss function based on the trajectory of the ADV; and
evaluate a performance of the prediction module based on the weighted loss function to improve the performance of the prediction module to increase a safety and comfort of the ADV.

10. The non-transitory machine-readable medium of claim 9, wherein the loss function includes a mean waypoint distance error, and wherein the processor is further to
decompose the mean waypoint distance error into a first mean waypoint distance error perpendicular to a lane with a first weighting and a second mean waypoint distance error along the lane with a second weighting, wherein the first weighting is larger than the second weighting.

11. The non-transitory machine-readable medium of claim 9, wherein the loss function includes a final point distance error, and wherein the processor is further to
decompose the final point distance error into a first final point distance error perpendicular to a lane with a first weighting and a second final point distance error along the lane with a second weighting, wherein the first weighting is larger than the second weighting.

12. The non-transitory machine-readable medium of claim 9, wherein the loss function includes a location error, and wherein the processor is further to
decompose the location error into a speed error with a first weighting and a heading error with a second weighting, wherein the first weighting is larger than the second weighting.

13. The non-transitory machine-readable medium of claim 9, wherein the processor is further to
determine each weighing of the multiple weightings based on an impact of a weighting to the trajectory of the ADV.

14. The non-transitory machine-readable medium of claim 9, wherein the processor is further to
determine each weighing of the multiple weightings based on a performance of the planning module based on the trajectory of the ADV.

15. The non-transitory machine-readable medium of claim 9, wherein the loss function includes a plurality of losses corresponding to a plurality of driving scenarios, each loss corresponding to a driving scenario.

16. The non-transitory machine-readable medium of claim 15, wherein the processor is further to
determine a driving scenario from the plurality of driving scenarios;
determine a corresponding loss from the plurality of losses in response to the driving scenario.

17. A data processing system, comprising:
a processor; and
a memory coupled to the processor to store instructions, which when executed by the processor, cause the processor to:
predict a trajectory of an obstacle by a prediction module of an autonomous driving vehicle (ADV);
plan a trajectory of the ADV based on the trajectory of the obstacle by a planning module of the ADV;
decompose a loss function of an analysis model of the prediction module into multiple components with multiple weightings to generate a weighted loss function based on the trajectory of the ADV; and
evaluate a performance of the prediction module based on the weighted loss function to improve the performance of the prediction module to increase a safety and comfort of the ADV.

18. The data processing system of claim 17, wherein the loss function includes a mean waypoint distance error, and wherein the processor is further to
decompose the mean waypoint distance error into a first mean waypoint distance error perpendicular to a lane with a first weighting and a second mean waypoint distance error along the lane with a second weighting, wherein the first weighting is larger than the second weighting.

19. The data processing system of claim 17, wherein the loss function includes a final point distance error, and wherein the processor is further to
decompose the final point distance error into a first final point distance error perpendicular to a lane with a first weighting and a second final point distance error along the lane with a second weighting, wherein the first weighting is larger than the second weighting.

20. The data processing system of claim 17, wherein the loss function includes a location error, and wherein the processor is further to
decompose the location error into a speed error with a first weighting and a heading error with a second weighting, wherein the first weighting is larger than the second weighting.
